(19) United States
(12) Patent Application Publication
(10) Pub. No.: US 2026/0161876 A1
(43) Pub. Date: Jun. 11, 2026

(54) METHOD OF SIMULATING AND VERIFYING FULL-CHIP LAYOUT

(71) Applicant: Samsung Electronics Co., Ltd., Suwon-si (KR)

(72) Inventors: Kyungmi Yeom, Suwon-si (KR); Alexander Schmidt, Suwon-si (KR); Anthony Pierre Gerard Payet, Yokohama (JP); Chihak Ahn, San Jose, CA (US); Yutaka Nishizawa, Yokohama (JP); Geunsang Yoo, Suwon-si (KR); Sungjin Kim, Suwon-si (KR); Seungmin Lee, Suwon-si (KR); Joohyun Jeon, Suwon-si (KR)

(21) Appl. No.: 19/212,827

(22) Filed: May 20, 2025

Related U.S. Application Data
(60) Provisional application No. 63/730,107, filed on Dec. 10, 2024.

(51) Int. Cl. G06F 30/398

(52) U.S. Cl. CPC G06F 30/398

(57) ABSTRACT

A method of simulating a layout of an integrated circuit manufactured by a semiconductor process may include generating tiled layout data including a plurality of tiles by tiling layout data defining the layout of the integrated circuit, generating a simulation structure and a mesh structure based on the tiled layout data, generating a stress simulation result value by performing a stress simulation on each of the plurality of tiles, generating a local stress value by performing a stress averaging task based on the stress simulation result value, and generating a warpage simulation result value by performing a warpage simulation based on the local stress value. The layout data may include at least one layer.

### CROSS-REFERENCE TO RELATED APPLICATION

This application is based on and claims priority to U.S. Provisional Application No. 63/730,107, filed on Dec. 10, 2024, in the U.S. Patent and Trademark Office, the disclosure of which is incorporated by reference herein in its entirety.

### TECHNICAL FIELD

The inventive concept relates to an integrated circuit layout simulation, and more particularly, to a method of simulating and verifying a full-chip layout.

### BACKGROUND

To increase the capacity of a semiconductor device and reduce manufacturing costs, many efforts have been made to increase the integration of semiconductor devices. In particular, the integration of semiconductor devices is an important factor in determining the prices of a product. As the integration of a semiconductor device is largely determined by an area occupied by a unit cell, it is very important to efficiently design the layout of the semiconductor device. Generally, designing the layout of a semiconductor device using a layout design tool takes a lot of time and trial and error, and thus reducing the layout design time is also very important. Accordingly, technology to shorten a verification time for layout design and verify the layout to prevent layout defects from occurring in the later process stage may be beneficial.

### SUMMARY

The inventive concept provides a method of verifying defects of a layout by automatically identifying risky patterns that may occur in a microprocess through a full-chip layout simulation that reflects process conditions, and by predicting warpage of a chip or wafer.

The technical objectives to be achieved by the inventive concept are not limited to the above-described objectives, and other technical objectives that are not mentioned herein will be clearly understood by a person skilled in the art from the description of the inventive concept hereinafter.

According to aspects of the inventive concept, a method of simulating a layout of an integrated circuit manufactured by a semiconductor process includes generating tiled layout data including a plurality of tiles by tiling layout data defining the layout of the integrated circuit, wherein the layout data may include at least one layer, generating a simulation structure and a mesh structure based on the tiled layout data, generating a stress simulation result value by performing a stress simulation on each of the plurality of tiles, generating a local stress value by performing a stress averaging task based on the stress simulation result value, and generating a warpage simulation result value by performing a warpage simulation based on the local stress value.

According to aspects of the inventive concept, a method of simulating a layout of an integrated circuit manufactured by a semiconductor process includes generating tiled layout data including a plurality of tiles by tiling layout data defining the layout of the integrated circuit, wherein the layout data may include at least one layer, generating a simulation structure and a mesh structure based on the tiled layout data, generating a stress simulation result value by performing a stress simulation on each of the plurality of tiles, and detecting a weak pattern from among a plurality of patterns included in the plurality of tiles based on the stress simulation result value.

According to aspects of the inventive concept, a method of simulating a layout of an integrated circuit manufactured by a semiconductor process includes generating tiled layout data including a plurality of tiles by tiling layout data defining the layout of the integrated circuit, wherein the layout data may include at least one layer, generating a simulation structure and a mesh structure based on the tiled layout data, generating a stress simulation result value by performing a stress simulation on each of the plurality of tiles, generating a local stress value by performing a stress averaging task based on the stress simulation result value, detecting a weak pattern from among a plurality of patterns included in the plurality of tiles based on the stress simulation result value, and generating a warpage simulation result value by performing a warpage simulation based on the local stress value and the weak pattern.

### BRIEF DESCRIPTION OF THE DRAWINGS

Embodiments will be more clearly understood from the following detailed description taken in conjunction with the accompanying drawings in which:

FIG. 1 is a flowchart showing a method of designing and manufacturing a semiconductor device, according to embodiments;

FIG. 2 is a block diagram of a layout simulation system according to embodiments;

FIG. 3 is a flowchart showing a method of simulating a layout of an integrated circuit, according to embodiments;

FIG. 4 is a flowchart showing a method of tiling full-chip layout data according to embodiments;

FIG. 5 is a diagram illustrating a process of tiling full-chip layout data;

FIG. 6 is a diagram illustrating tiles generated by tiling the full-chip layout data;

FIG. 7 is a diagram illustrating rounding of layout data;

FIG. 8 is a diagram illustrating tiles according to embodiments;

FIG. 9 is a flowchart showing a full-chip stress simulation according to embodiments;

FIGS. 10 and 11 are perspective views illustrating a simulation structure according to embodiments;

FIGS. 12 and 13 are diagrams illustrating a mesh according to embodiments;

FIG. 14 is a diagram illustrating an influence of process conditions on a stress simulation, according to embodiments;

FIGS. 15 and 16 are diagrams illustrating a stress simulation according to embodiments;

FIG. 17 is a flowchart showing a warpage simulation method according to embodiments;

FIG. 18 is a flowchart showing an embedded warpage simulation method according to embodiments;

FIGS. 19A, 19B, and 19C are diagrams illustrating a local stress averaging task according to embodiments;

FIG. 20 is a diagram illustrating a warpage simulation according to embodiments;

FIGS. 21 and 22 are diagrams illustrating an embedded warpage simulation according to embodiments;

FIG. 23 is a flowchart showing a weak pattern detection method according to embodiments;

FIG. 24 is a flowchart showing a weak pattern detection method according to embodiments;

FIG. 25 is a graph showing a method of calculating a crack probability, according to embodiments; and

FIG. 26 is a block diagram showing a computer system according to embodiments.

### DETAILED DESCRIPTION

Hereinafter, example embodiments will be described in detail with reference to the attached drawings. In the description with reference to the drawings, the same or corresponding constituents are indicated by the same reference numerals and redundant descriptions thereof may be omitted.

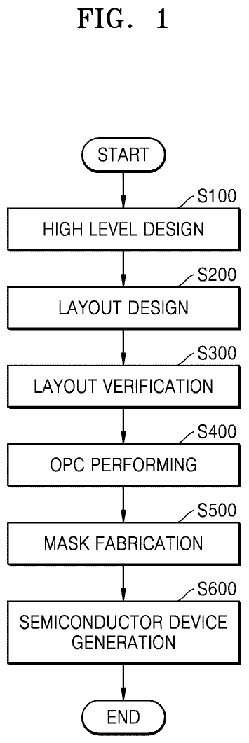

FIG. 1 is a flowchart showing a method of designing and manufacturing a semiconductor device, according to embodiments.

Referring to FIG. 1, a method of designing and manufacturing a semiconductor device may include operations S100, S200, S300, S400, S500, and S600.

In operation S100, a high level design of a semiconductor device may be performed. The high level design may mean taking an idea for a product and describing an integrated circuit based on the idea in a computer language. For example, a semiconductor integrated circuit may be represented in detail by register transfer level (RTL) coding or simulation. Code generated by the RTL coding may be converted into a netlist to be synthesized into the entire semiconductor device. A synthesized schematic circuit may be verified using a simulation tool, and an adjustment process may be involved depending on a result of verification.

In operation S200, a layout design for implementing a logically completed semiconductor integrated circuit on a silicon substrate may be performed. A layout may be configured by placing layout patterns of various shapes and sizes at locations and in shapes required for configuring a circuit of a semiconductor device. The layout design may mean a procedure for defining the shapes and sizes of patterns to form transistors and metal wires to be actually formed on a silicon substrate.

The layout design may be performed based on the schematic circuit synthesized in operation S100 or a netlist according thereto. The layout design may include a procedure for placing various standard cells provided from a cell library according to the prescribed design rule and a routing procedure for connecting the standard cells. The cell library may include information about the operation, speed, and power consumption of the standard cell.

For example, to form an inverter circuit on an actual silicon substrate, a user may search and select an appropriate one of inverters predefined in the cell library. Circuit patterns such as, for example, a P-channel metal-oxide-semiconductor (PMOS), an N-channel metal-oxide-semiconductor (NMOS), an N-WELL and/or P-WELL, a gate electrode, and metal wires placed thereon may be appropriately placed based on the selected inverter. Subsequently, routing may be performed for the selected and placed standard cells. In detail, high wires (routing patterns) may be placed on the placed standard cells. As the routing is performing, the placed standard cells may be connected to each other according to the design. The placement and routing of the standard cells may be automatically performed by a placement and routing tool.

In operation S300, layout verification may be performed. The layout verification may mean a procedure for checking whether a designed layout matches the design rule. The layout verification may include a design rule checking (DRC) process for verifying whether a layout matches the design rule, an electrical rule checking (ERC) process for verifying whether there is any internal electrical disconnection, and a layout vs schematic (LVS) process for checking whether a layout matches a gate-level netlist, or the like. The verification of a layout may be achieved by simulating a full-chip layout through a full-chip layout simulation system. In the present specification, the full-chip layout simulation system may be briefly referred to as a layout simulation system. The following descriptions are based on that the verification of a layout is performed in units of chips. However, the inventive concept is not limited thereto. The verification of a layout may be performed in units of shots or wafers, not in units of chips. In some embodiments, when the verification of a layout is performed in units of shots or wafers, the verification may be performed considering that a test element group (TEG) is arranged between chips. TEG may refer to a group in which elements for test are gathered in a semiconductor manufacturing process.

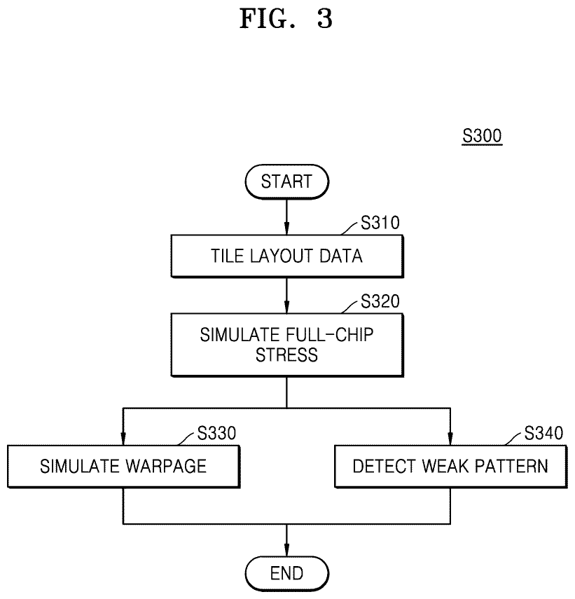

The layout verification performed in operation S300 may include a physical-mechanical analysis with respect to a full-chip layout. For example, a stress value for each coordinate of a layout may be simulated in combination with a process physical model (e.g.: a simulation model representing temperature, time, physical properties, or the like related to deposition, etch, a chemical mechanical planarization (CMP) process), and a warpage simulation may be performed based on a result of the simulation or a weak pattern may be additionally identified. A detailed description about operation S300 is presented below with reference to FIG. 3.

In operation S400, optical proximity correction (OPC) may be performed. A distortion phenomenon that may occur when a photolithography process is performed in the subsequent operation on the layout patterns generated through operations S200 and S300 may be corrected by performing the OPC. In other words, a distortion phenomenon, such as refraction or a process effect, occurring due to the properties of light when a photolithography process is performed in the subsequent operation (e.g., S600) may be corrected by performing OPC. By performing OPC, the shape and location of the designed layout patterns may be finely biased.

In operation S500, a photomask may be fabricated based on the layout biased by OPC. The photomask may be fabricated in a manner that describes layout patterns using a chromium layer coated on a glass substrate, but the inventive concept is not limited thereto.

In operation S600, a semiconductor device may be manufactured by using the photomask. In a semiconductor device manufacturing process, various methods of an exposure process and an etching process may be repeated. Accordingly, the shape of patterns formed through the layout design may be sequentially formed on a silicon substrate.

According to the layout verification method according to embodiments, through a full-chip layout simulation reflecting process conditions, risky pattern that may be generated in the microprocess may be automatically identified, and defects in the layout may be verified by predicting the warpage of the chip or wafer. In the specification, warpage may refer to a distortion phenomenon that occurs in a semiconductor chip or wafer.

As such, by verifying the defects of a layout, potential defects in the layout may be quickly discovered during the initial design operation of an integrated circuit, which may remarkably reduce the development cost and time of the integrated circuit. In the following description, operation S300 is described in detail.

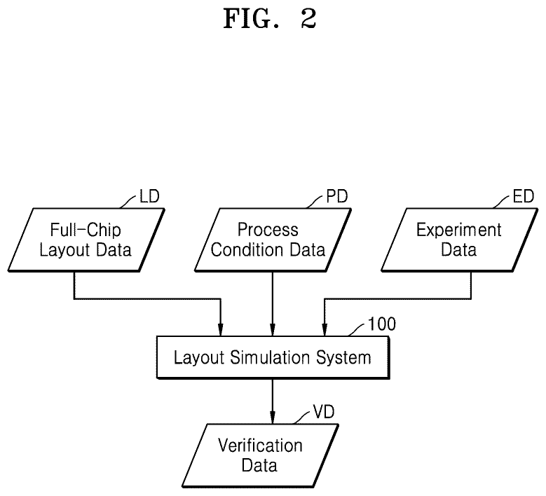

FIG. 2 is a block diagram of a layout simulation system 100 according to embodiments.

Referring to FIG. 2, the layout simulation system 100 may be a system that performs full-chip layout simulation and verification for performing operation S300 of FIG. 1.

The layout simulation system 100 may receive full-chip layout data LD, process condition data PD, and experiment data ED. The layout simulation system 100 may output verification data VD corresponding to the full-chip layout data LD by performing a simulation on the full-chip layout data LD based on the full-chip layout data LD, the process condition data PD, and the experiment data ED.

The full-chip layout data LD may include geometrical information about the layout of an integrated circuit. For example, the full-chip layout data LD may have a certain format for defining the layout of an integrated circuit, for example, graphic design system (GDS). The full-chip layout data LD may define structures formed in a plurality of layers, for example, a substrate, an active layer, a wire layer, or the like, and thus a three-dimensional structure of the layout may be defined.

In embodiments, the format of the full-chip layout data LD may include not only GDS, but also an open artwork system interchange standard (OAS) or a structure file (STR).

In embodiments, the full-chip layout data LD may be referred to as layout data.

The process condition data PD may include parameters (e.g., a temperature, etc.) about a semiconductor process for manufacturing an integrated circuit. The parameters may include parameters used for controlling processes or parameters measured in the semiconductor process. Furthermore, the process condition data PD may include information about dispersion (or variability) of parameters. For example, the process condition data PD may include the average and dispersion of parameters.

In embodiments, the process condition data PD may include an elastic modulus value which indicates how hard a material used in the semiconductor process is, a Poisson's ratio which indicates a rate at which a material stretches in one direction when compressed in another direction, and a temperature value operating in each process and a duration of each process.

In embodiments, the process condition data PD may be selectively input to the layout simulation system 100.

The experiment data ED may be data including a measured value for an actual integrated circuit corresponding to the (full-chip) layout data LD. For example, the experiment data ED may include a crack occurrence probability at a specific coordinate point on an integrated circuit. As used herein, the experiment data ED may also be referred to as pre-input experiment data.

In embodiments, the experiment data ED may be selectively input to the layout simulation system 100.

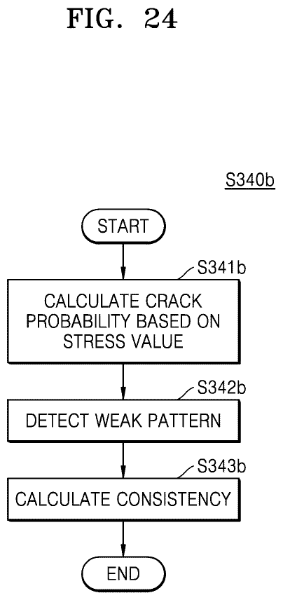

The verification data VD may include at least one of a warpage simulation result value and consistency of crack probability. The warpage simulation result value is described below with reference to FIG. 3, and the consistency of crack probability is described below with reference to FIG. 24.

FIG. 3 is a flowchart showing a method of simulating a layout of an integrated circuit, according to embodiments. In detail, FIG. 3 is a flowchart showing operation S300 of FIG. 1. FIG. 3 may be described with reference to FIGS. 1 and 2, redundant descriptions may be omitted.

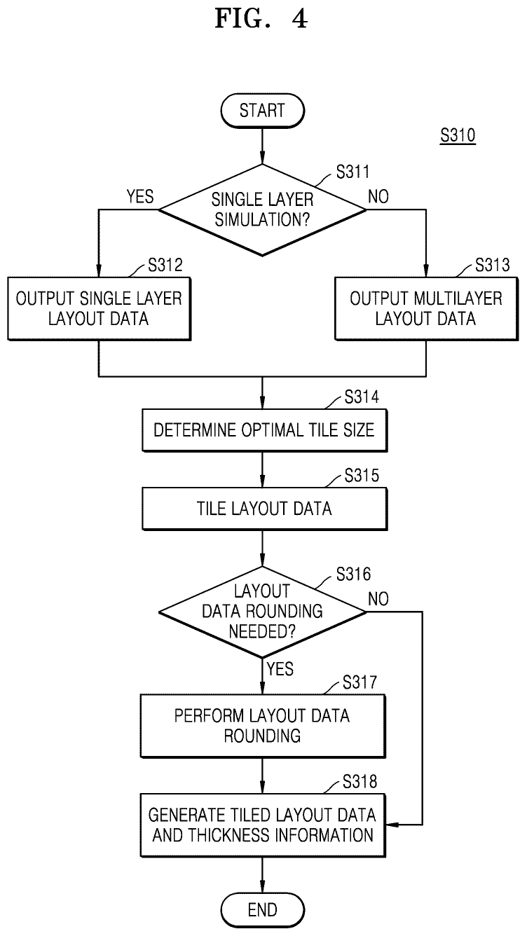

Referring to FIG. 3, in operation S310, the layout simulation system 100 may tile (or organize or process) layout data of an integrated circuit. In detail, the layout simulation system 100 may generate tiled layout data by tiling the full-chip layout data LD. In this state, information about the thickness of each layer constituting the tiled layout data may be generated together. The tiled layout data may include a plurality of tiles. A detailed description about operation S310 is described below with reference to FIG. 4.

In some embodiments, the tiling of the full-chip layout data LD by the layout simulation system 100 may be referred to as layout processing.

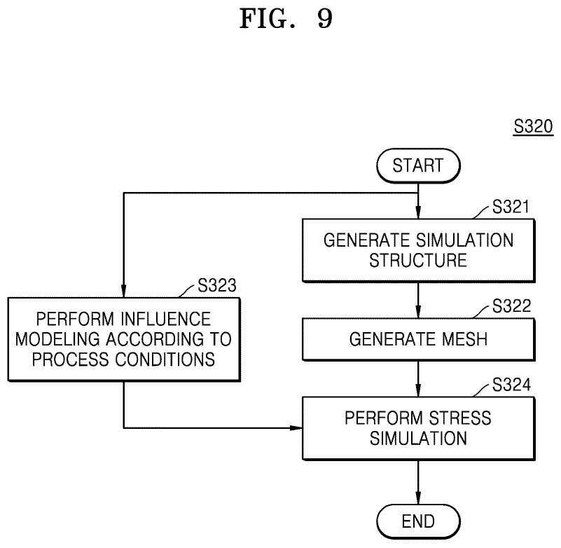

In operation S320, the layout simulation system 100 may perform a full-chip stress simulation. In detail, the layout simulation system 100 may perform a stress simulation for each tile based on the tiled layout data so that a stress simulation result value corresponding to each tile may be generated. The stress simulation result value may include coordinates of a particular position in the corresponding tile and a stress value according to the corresponding coordinates. A detailed description about operation S320 is described below with reference to FIG. 9.

In operation S330, the layout simulation system 100 may perform a warpage simulation based on the stress simulation result value generated in operation S320. In detail, the layout simulation system 100 may simulate how warpage occurs on a chip or wafer corresponding to the full-chip layout data LD.

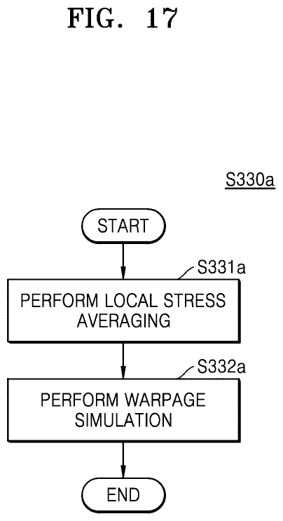

In embodiments, the layout simulation system 100 may perform a local stress averaging task for each tile and perform a warpage simulation for an integrated circuit based on a result of the local stress averaging task. A detailed description thereon is described below with reference to FIG. 17.

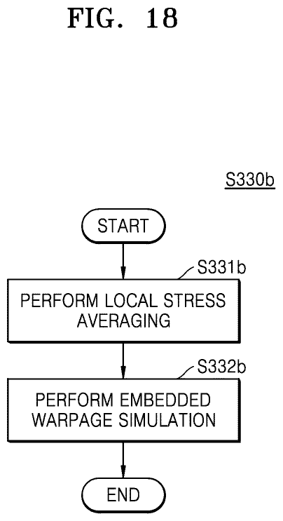

In embodiments, the layout simulation system 100 may perform the local stress averaging task for each tile, and perform an embedded warpage simulation for an integrated circuit additionally considering the weak pattern detected according to operation S340. A detailed description thereon is described below with reference to FIG. 18.

In operation S340, the layout simulation system 100 may detect a weak pattern based on the stress simulation result value generated in operation S320.

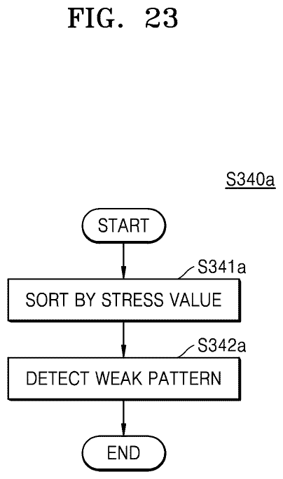

In embodiments, when the experiment data ED input to the layout simulation system 100 is not present, the layout simulation system 100 may detect a weak pattern by comparing the stress simulation result value generated in operation S320 with a reference stress value. A detailed description thereon is described below with reference to FIG. 23.

In embodiments, when the experiment data ED input to the layout simulation system 100 is present, the layout simulation system 100 may detect a weak pattern by comparing the stress simulation result value generated in operation S320 with the experiment data ED. A detailed description thereon is described below with reference to FIG. 24.

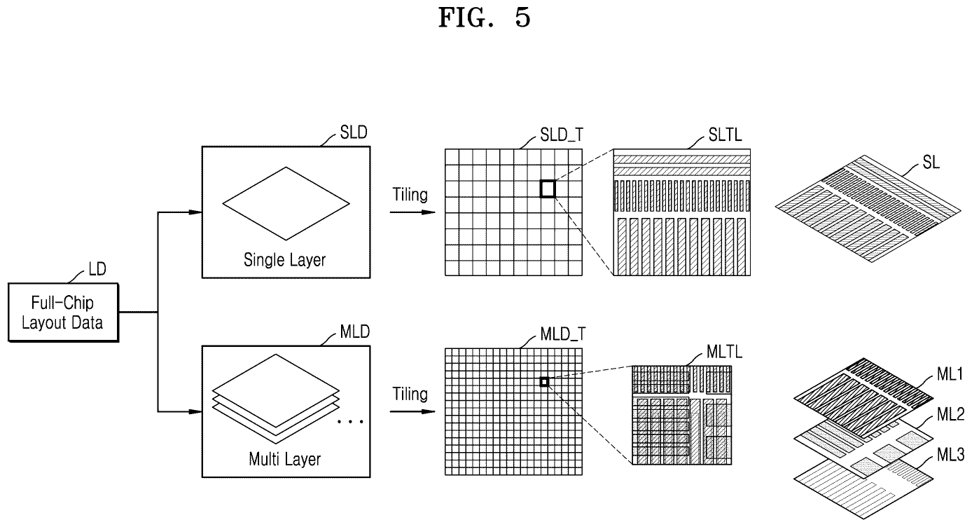

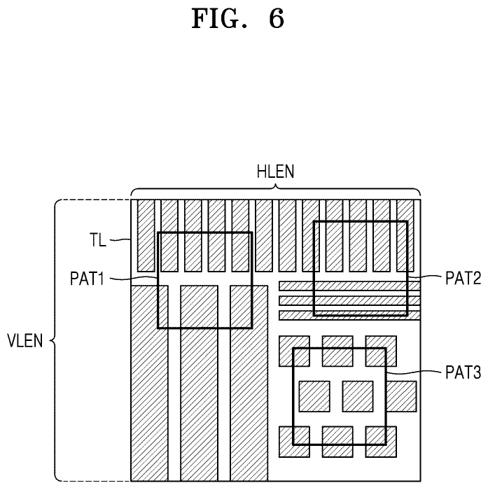

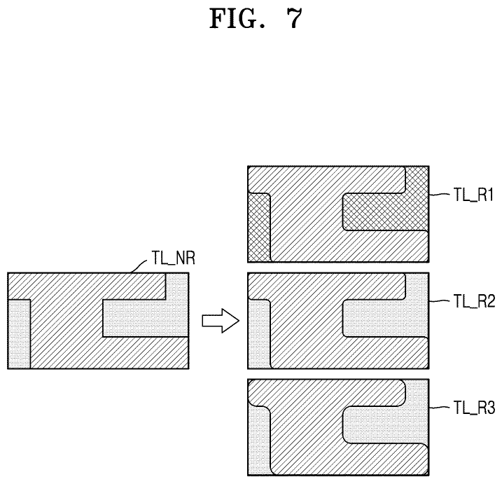

FIG. 4 is a flowchart showing a method of tiling full-chip layout data according to embodiments. In detail, FIG. 4 is a flowchart showing operation S310 of FIG. 3. FIG. 5 is a diagram illustrating a process of tiling full-chip layout data. FIG. 6 is a diagram illustrating tiles generated by tiling the full-chip layout data. FIG. 7 is a diagram illustrating rounding of layout data. FIGS. 4 to 7 may be described with reference to FIGS. 1 to 3, and redundant descriptions thereof may be omitted.

Referring to FIGS. 4 and 5, in operation S311, the layout simulation system 100 may determine whether a simulation for the full-chip layout data LD is a single layer simulation or a multilayer simulation according to a pre-input setting value or user's manipulation.

In operation S312, when a result determined in operation S311 is a single layer simulation for the full-chip layout data LD, the layout simulation system 100 may output single layer layout data SLD that is extracted from the full-chip layout data LD. In this state, the single layer layout data SLD may be data for any one layer selected from among a plurality of layers constituting the full-chip layout data LD and may be a layer subject to analysis in the subsequent simulation process.

In operation S313, when the result determined in operation S311 is a multilayer simulation for the full-chip layout data LD, the layout simulation system 100 may output multilayer layout data MLD from the full-chip layout data LD. In this state, the multilayer layout data MLD that is output may be data for at least one layer selected from among the plurality of layers constituting the full-chip layout data LD and may be a layer subject to analysis in the subsequent simulation process.

In operation S314, the layout simulation system 100 may determine an optimal tile size.

Referring to FIG. 6, the optimal tile size may be defined by a horizontal length HLEN and a vertical length VLEN of a tile, and the horizontal length HLEN and the vertical length VLEN of the tile may be respectively less than a horizontal length and a vertical length of the single layer layout data SLD or the multilayer layout data MLD. In this state, as illustrated in FIG. 6, the horizontal length HLEN and the vertical length VLEN of the tile may be identical to each other. However, this is an example for explanation, and the inventive concept is not limited thereto.

In embodiments, the optimal tile size may be a value previously input to the layout simulation system 100.

In embodiments, the optimal tile size may be a value input by a user who operates the layout simulation system 100.

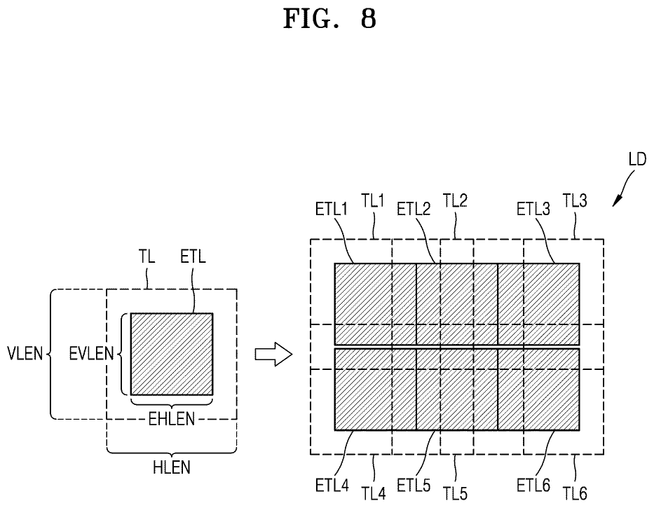

In embodiments, the optimal tile size may be a value considering an effective tile size to remove a boundary condition effect. The boundary condition effect is described below with reference to FIG. 8.

Referring back to FIGS. 4 and 5, in operation S315, the layout simulation system 100 may tile the layout data according to the tile size determined in operation S314. The tiled layout data may include a plurality of tiles.

In embodiments, each tile constituting the layout data may include a plurality of patterns. For example, as illustrated in FIG. 6, a tile TL may include a first pattern PAT1, a second pattern PAT2, and a third pattern PAT3. In FIG. 6 the tile TL is illustrated as including three patterns, which is an example and the present disclosure is not limited thereto. It will be understood that it is possible to include more or less than three patterns.

In operation S316, the layout simulation system 100 may determine whether to perform a rounding task for the layout data according to a pre-input setting value or user's manipulation.

The rounding task may mean a task to round the corners of a pattern within a tile. In the semiconductor process, right-angled corners on a layout are often slightly rounded due to process limitations or optical proximity correction (OPC) rather than being implemented as is during actual manufacturing. Accordingly, the layout simulation system 100 according to embodiments may provide, during simulation or design verification, a shape close to the actual result by reflecting in advance a round corner effect that occurs in the actual process.

In operation S317, when it is determined in operation S316 to perform the rounding task, the layout simulation system 100 may perform a rounding task for the layout data. The rounding task may be performed based on a preset curvature value or a curvature value set by a user who operates the layout simulation system 100.

In embodiments, referring to FIG. 7, when the preset curvature value is a first curvature, a tile TL_NR may be rounded into a first rounded tile TL_R1. When the preset curvature value is a second curvature, the tile TL_NR may be rounded into a second rounded tile TL_R2. When the preset curvature value is a third curvature, the tile TL_NR may be rounded into a third rounded tile TL_R3. In this state, the third curvature may be greater than the second curvature, and the second curvature may be greater than the first curvature. For example, corners of the third rounded tile TL_R3 may be less angular (i.e., smoother) or more rounded than corners of the first rounded tile TL_R1 and the second rounded tile TL_R2.

In embodiments, the rounding task for the layout data may be performed for each tile.

In operation S318, the layout simulation system 100 may generate tiled layout data, and generate thickness information corresponding to the tiled layout data.

In embodiments, the layout simulation system 100 may generate tiled single layer layout data SLD_T including a plurality of tiles by tiling the single layer layout data SLD. For example, a tile SLTL included in the tiled single layer layout data SLD_T may be a tile formed as a single layer SL. Furthermore, the layout simulation system 100 may generate thickness information corresponding to the single layer SL.

In embodiments, the layout simulation system 100 may generate tiled multilayer layout data MLD_T including a plurality of tiles by tiling the multilayer layout data MLD. For example, a tile MLTL included in the tiled multilayer layout data MLD_T may be a multilayer tile including a first layer ML1, a second layer ML2, and a third layer ML3. Furthermore, the layout simulation system 100 may generate thickness information corresponding to each of the first layer ML1, the second layer ML2, and the third layer ML3.

FIG. 8 is a diagram illustrating tiles according to embodiments. FIG. 8 may be described with reference to FIGS. 1 to 6, and redundant descriptions thereof may be omitted.

As the overall layout of a semiconductor chip is very large and complicated, simulating the overall layout at once may result in an excessively large amount of computation. Accordingly, the layout simulation system 100 according to embodiments may individually perform a simulation by dividing the full-chip layout data LD into multiple tiles. In this state, when the full-chip layout data LD is divided into multiple tiles, each tile may have an artificial boundary. This boundary is a continuous area in an actual chip, but in a tile unit simulation, the boundary is broken so that a pattern or stress distribution located at the boundary may appear to be different from the actual one. For example, at the edge of a tile, interaction with the surrounding environment is not taken into account so that the distribution of a stress result value obtained through simulation may be distorted. In some embodiments, a phenomenon causing the distortion may be referred to as a boundary condition effect.

The layout simulation system 100 according to embodiments may prevent distortion in the simulation due to the boundary condition effect by tiling the full-chip layout data LD based on an effective tile ETL. In other words, as the boundary condition effect occurs at the edge of a tile, the layout simulation system 100 may remove the boundary effect by performing a simulation considering only the effective area within the tile. Accordingly, the layout simulation system 100 may produce a simulation result close to the actual process.

Referring to FIG. 8, the tile TL may include the effective tile ETL. A horizontal size EHLEN of the effective tile ETL may be less than a horizontal size HLEN of the tile TL. A vertical size EVLEN of the effective tile ETL may be less than a vertical size VLEN of the tile TL.

The tile TL may be divided into two types of areas. In the specification, a first area of the tile TL may be an area corresponding to the effective tile ETL, and the second area of the tile TL may refer to an area that does not correspond to the effective tile ETL. For example, a second area may refer to an area excluding the first area from the tile TL. In this state, the first area of the tile TL and first areas of other tiles may not overlap each other. The second area of the tile TL may overlap at least part of another tile.

In embodiments, the full-chip layout data LD may be tiled with six tiles. In FIG. 8, the tiling of the full-chip layout data LD with six tiles is an example for explanation, and the inventive concept is not limited thereto. In this state, a first tile TL1 may include a first effective tile ETL1, a second tile TL2 may include a second effective tile ETL2, a third tile TL3 may include a third effective tile ETL3, a fourth tile TL4 may include a fourth effective tile ETL4, a fifth tile TL5 may include a fifth effective tile ETL5, and a sixth tile TL6 may include a sixth effective tile ETL6.

The second area of each tile may overlap at least part of another tile. For example, the second area of first tile TL1 may overlap at least parts of the second tile TL2, the fourth tile TL4, and the fifth tile TL5. The second area of the second tile TL2 may overlap at least parts of the first tile TL1, the third tile TL3, the fourth tile TL4, the fifth tile TL5, and the sixth tile TL6. The second area of the third tile TL3 may overlap at least parts of the second tile TL2, the fifth tile TL5, and the sixth tile TL6. The second area of the fourth tile TL4 may overlap at least parts of the first tile TL1, the second tile TL2, and the fifth tile TL5. The second area of the fifth tile TL5 may overlap at least parts of the first tile TL1, the second tile TL2, the third tile TL3, the fourth tile TL4, and the sixth tile TL6. The second area of the sixth tile TL6 may overlap at least parts of the second tile TL2, the third tile TL3, and the fifth tile TL5.

The first area of each tile (i.e., an area corresponding to the effective tile) does not overlap at least part of another tile and may be arranged adjacent to the first area of another tile. For example, the first effective tile ETL1 may be arranged adjacent to the second effective tile ETL2 and the fourth effective tile ETL4. The second effective tile ETL2 may be arranged adjacent to the first effective tile ETL1, the third effective tile ETL3, and the fifth effective tile ETL5. The third effective tile ETL3 may be arranged adjacent to the second effective tile ETL2 and the sixth effective tile ETL6. The fourth effective tile ETL4 may be arranged adjacent to the first effective tile ETL1 and the fifth effective tile ETL5. The fifth effective tile ETL5 may be arranged adjacent to the second effective tile ETL2, the fourth effective tile ETL4, and the sixth effective tile ETL6. The sixth effective tile ETL6 may be arranged adjacent to the third effective tile ETL3 and the fifth effective tile ETL5.

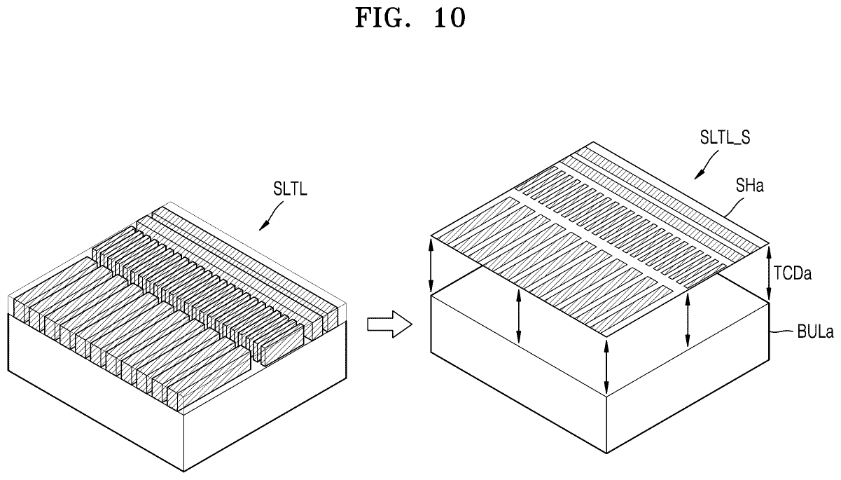

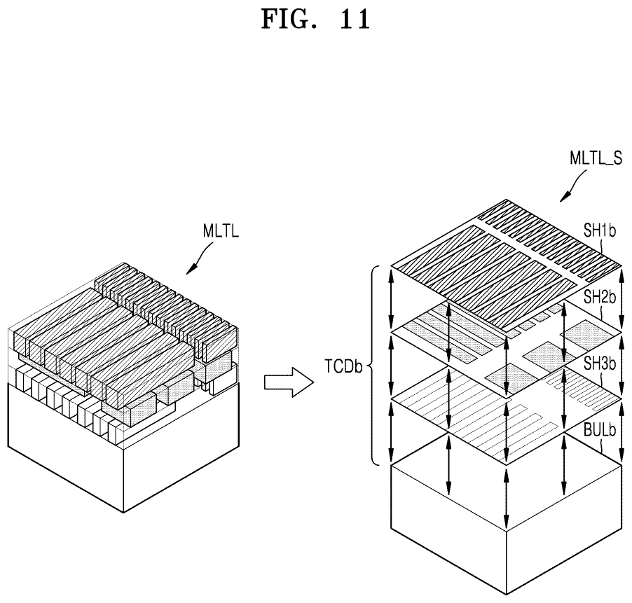

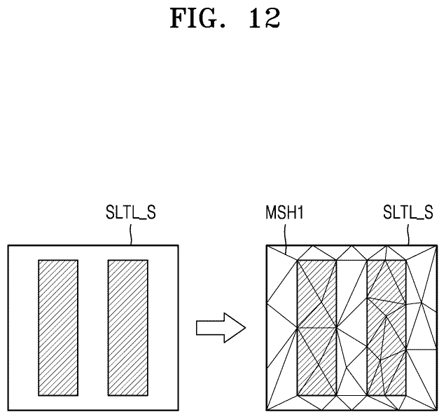

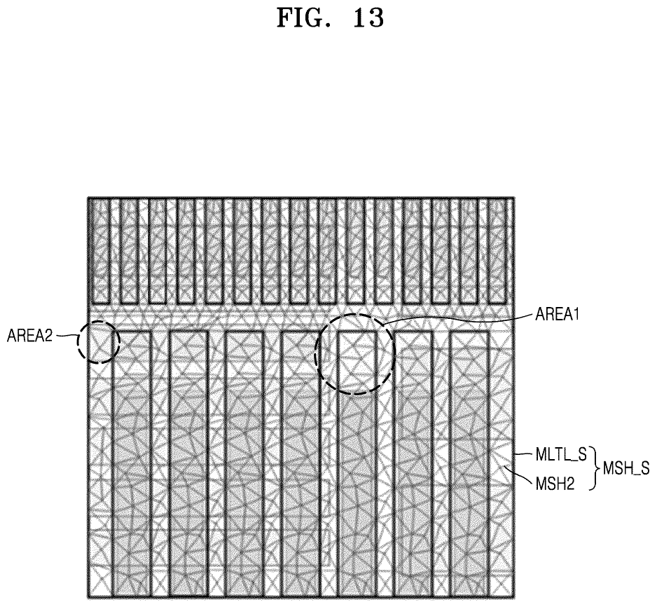

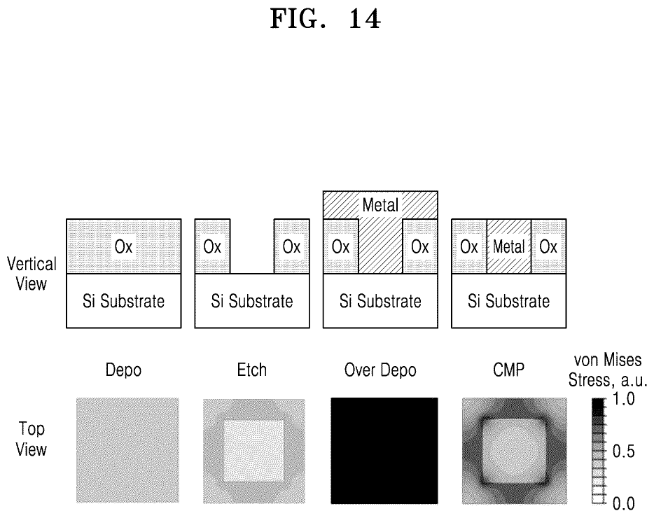

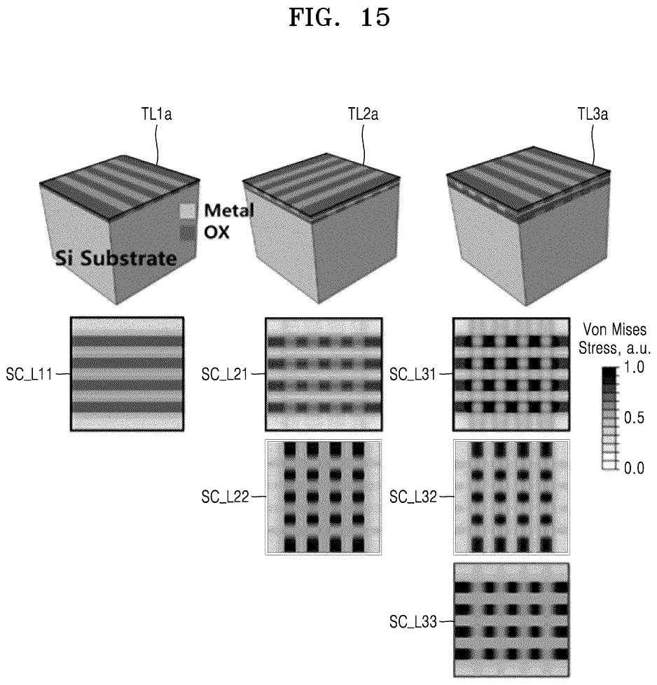

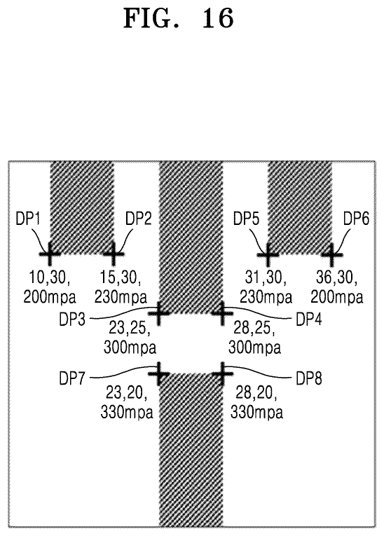

FIG. 9 is a flowchart showing a full-chip stress simulation according to embodiments. In detail, FIG. 9 is a flowchart showing operation S320 of FIG. 3. FIGS. 10 and 11 are perspective views illustrating a simulation structure according to embodiments. FIGS. 12 and 13 are diagrams illustrating a mesh according to embodiments. FIG. 14 is a diagram illustrating an influence of process conditions on a stress simulation, according to embodiments. FIGS. 15 and 16 are diagrams illustrating a stress simulation according to embodiments. FIGS. 9 to 16 may be described with reference to FIGS. 1 to 4, and redundant descriptions thereof may be omitted.

Referring to FIGS. 9, 10, and 11, in operation S321, the layout simulation system 100 may generate a simulation structure in a tile unit based on the tiled layout data and thickness information generated through operation S310.

The tiled layout data may have a three-dimensional (3D) structure. However, when all areas are 3D-modeled, an amount of computation needed for simulation may be very large. Accordingly, the layout simulation system 100 may model a layer included in each tile in a shell structure. The shell structure may refer to a model that is simplified to reduce the amount of computation while reflecting that the layout data is in 3D.

Referring to FIG. 10, when the tiled single layer layout data SLD_T is configured with a single layer, the layout simulation system 100 may generate a simulation structure SLTL S corresponding to the tile SLTL based on the tile SLTL. The simulation structure SLTL_S may include a shell structure SHa, a bulk structure BULa, and a tie condition TCDa. The shell structure SHa may represent the single layer SL of the tile SLTL in a plan view. The bulk structure BULa may represent the layout of a substrate in the tile SLTL in 3D. The tie condition TCDa may be information indicating connection information between the bulk structure BULa and the shell structure SHa. For example, the tie condition TCDa may be information indicating that the bulk structure BULa and the shell structure SHa are connected to each other.

Referring to FIG. 11, when the tiled layout data is the tiled multilayer layout data MLD_T, the layout simulation system 100 may generate a simulation structure MLTL S corresponding to the tile MLTL based on the tile MLTL. The simulation structure MLTL_S may include a first shell structure SH1b, a second shell structure SH2b, a third shell structure SH3b, a bulk structure BULb, and a tie condition TCDb. The first shell structure SH1b, the second shell structure SH2b, and the third shell structure SH3b may respectively correspond to the first layer ML1, the second layer ML2, and the third layer ML3 constituting the tile MLTL which are represented in a plan view. The bulk structure BULb may represent the layout of a substrate in the tile MLTL in 3D. The tie condition TCDb may indicate connection information between the bulk structure BULb and the first shell structure SH1b, connection information between the first shell structure SH1b and the second shell structure SH2b, and connection information between the second shell structure SH2b and the third shell structure SH3b. For example, the tie condition TCDb may include information indicating that the bulk structure BULb and the first shell structure SH1b, information indicating that the first shell structure SH1b and the second shell structure SH2b are connected to each other, and information indicating that the second shell structure SH2b and the third shell structure SH3b are connected to each other.

For convenience of explanation, in the following description, in describing the layout simulation, the “tile” may refer to the simulation structure SLTL S or the simulation structure MLTL_S.

Referring to FIGS. 9, 12, and 13, in operation S322, the layout simulation system 100 may generate a mesh for the simulation structure generated in operation S321. The mesh may refer to a grid or network that divides a complicated geometry into smaller elements to perform simulations or analyses (e.g.: stress, heat, electromagnetic analysis, etc.).

Referring to FIG. 12, the layout simulation system 100 may calculate a physical phenomenon (e.g.: stress) occurring in the simulation structure SLTL_S by generating a mesh MSH1 in the simulation structure SLTL S.

Referring to FIG. 13, when the tiled multilayer layout data MLD_T includes a multilayer, the layout simulation system 100 may generate a mesh MSH2 by a focused mesh method. The focused mesh method may refer to a method of forming the mesh MSH2 intensively for a selected layer selected from the multilayer layout data including at least one layer, to reduce the calculation burden of the layout simulation system 100. That is, the focused mesh method may refer to a method for forming a mesh that is more refined in areas where higher precision is needed, such as, for example, high stress regions.

In embodiments, a mesh structure MSH_S may represent that the layout simulation system 100 generates the mesh MSH2 by using the focused mesh method on the simulation structure MLTL_S. The mesh MSH2 may be one that is generated by focusing on one layer (e.g., the first layer ML1 in FIG. 5 selected from among a plurality of layers constituting the simulation structure MLTL_S). For example, the density of the mesh MSH2 corresponding to the first layer ML1 may be greater than the density of the mesh MSH2 corresponding to the layers other than the first layer ML1. In other words, the density of the mesh MSH2 formed in a first area AREA1 that is part of the first layer ML1 may be greater than the density of the mesh MSH2 formed in a second area AREA2 that is part of the second layer ML2.

Referring to FIGS. 9 and 14, in operation S323, the layout simulation system 100 may extract physical properties information according to process conditions and intrinsic stress information through a process condition model corresponding to a semiconductor process needed to produce a semiconductor chip. In this state, the layout simulation system 100 may extract physical properties information and intrinsic stress information based on the process condition data PD including at least one process condition. The physical properties information and intrinsic stress information may be information to indicate an influence of each process on a stress simulation.

Referring to FIG. 14, shown are stress changes according to a deposition process, an etching process, an over-deposition process, and the CMP process in a process of manufacturing a semiconductor chip. In FIG. 14, the deposition, etching, over-deposition and CMP processes in a process of manufacturing a semiconductor chip are examples for explanation, and the inventive concept is not limited thereto.

In the specification, a stress value simulated through the layout simulation system 100 may be visually represented through a stress contour. The stress contour may refer to a visual representation of stress existing within a material or structure using shade gradation. The strength of stress may be represented by von Mises stress. In some embodiments, the unit in the von Mises stress may be Pascal or arbitrary units (a.u.) representing a relative magnitude of stress at each point on the stress contour. When the strength of stress is represented by stress contour, a portion having low stress may be represented by a lighter shade (e.g., on a grayscale, which may be at or near 0.0 a.u. von Mises stress), a portion having intermediate stress may be represented by a medium shade (e.g., on a grayscale, which may be at or near 0.5 a.u. von Mises stress), and a portion having high stress may be represented by a darker shade (e.g., on a grayscale, which may be at or near 1.0 a.u. von Mises stress). In this state, it may be intuitively seen through the stress contour that an area represented by a darker shade is a hot spot where stress is very high.

In embodiments, the physical properties information may include an elastic coefficient value, a Poisson's ratio, or the like of a material used in the semiconductor process.

In embodiments, as a new material is added in the deposition process, the intrinsic stress of a semiconductor chip may tend to increase. In the etching process, a phenomenon that the existing stress is partially relaxed as part of a material is removed may occur. In the over-deposition process, the intrinsic stress of a semiconductor chip may tend to increase again. In the CMP process, similarly to etching, the intrinsic stress may be relaxed. The intrinsic stress information may be information indicating a change in the intrinsic stress according to each process as above.

In embodiments, operation S323 may be performed in parallel with operation S310, operation S321, and operation S322. However, the inventive concept is not limited thereto, and operation S323 may be performed prior to or after operation S310, operation S321, and operation S322. Alternatively, operation S323 may be included in operation S324.

Referring to FIGS. 9, 15, and 16, in operation S324, the layout simulation system 100 may generate a stress simulation result value corresponding to each tile by performing a stress simulation on each of a plurality of tiles.

In embodiments, the layout simulation system 100 may generate a stress simulation result value by performing a simulation on each of a plurality of tiles based on the physical properties information and intrinsic stress information extracted in operation S323.

Referring to FIG. 15, when compared with a chip having a single layer structure, a chip having a multilayer structure may have a different stress distribution of the overall chip.

In embodiments, a first tile TL1a may be a single layer tile including a first layer. In this state, a first stress contour SC_L11 may be a stress contour corresponding to the first layer of the first tile TL1a.

In embodiments, a second tile TL2a may be a multilayer tile including two layers of a first layer and a second layer. In this state, a first stress contour SC_L21 may be a stress contour corresponding to the first layer of the second tile TL2a. A second stress contour SC_L22 may be a stress contour corresponding to the second layer of the second tile TL2a.

In embodiments, a third tile TL3a may be a multilayer tile including three layers of a first layer, a second layer, and a third layer. In this state, a first stress contour SC_L31 may be a stress contour corresponding to the first layer of the third tile TL3a. A second stress contour SC_L32 may be a stress contour corresponding to the second layer of the third tile TL3a. A third stress contour SC_L33 may be a stress contour corresponding to the third layer of the third tile TL3a.

Referring to FIG. 16, the stress simulation result value corresponding to each tile may include a coordinate value and a stress value of each of particular data points (e.g., a corner of a pattern) on a tile. In this state, the unit of the coordinate value may be nm, and the unit of the stress value may be Pascal.

For example, the coordinates of a first data point DP1 may be (10, 30), and the stress value of the first data point DP1 may be 200 mpa. The coordinates of a second data point DP2 may be (15, 30), and the stress value of the second data point DP2 may be 230 mpa. The coordinates of a third data point DP3 may be (23, 25), and the stress value of the third data point DP3 may be 300 mpa. The coordinates of a fourth data point DP4 may be (28, 25), and the stress value of the fourth data point DP4 may be 300 mpa. The coordinates of a fifth data point DP5 may be (31, 30), and the stress value of the fifth data point DP5 may be 230 mpa. The coordinates of a sixth data point DP6 may be (36, 30), and the stress value of the sixth data point DP6 may be 200 mpa. The coordinates of a seventh data point DP7 may be (23, 20), and the stress value of the seventh data point DP7 may be 330 mpa. The coordinates of an eighth data point DP8 may be (28, 20), and the stress value of the eighth data point DP8 may be 330 mpa.

FIG. 17 is a flowchart showing a warpage simulation method according to embodiments. In detail, FIG. 17 is a flowchart showing operation S330 of FIG. 3. FIG. 17 may be described with reference to FIGS. 1 to 4, and redundant descriptions thereof may be omitted.

Referring to FIG. 17, operation S330a may correspond to operation S330 of FIG. 3.

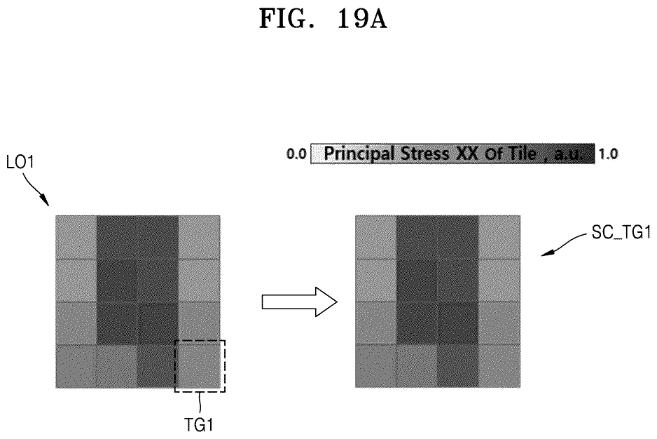

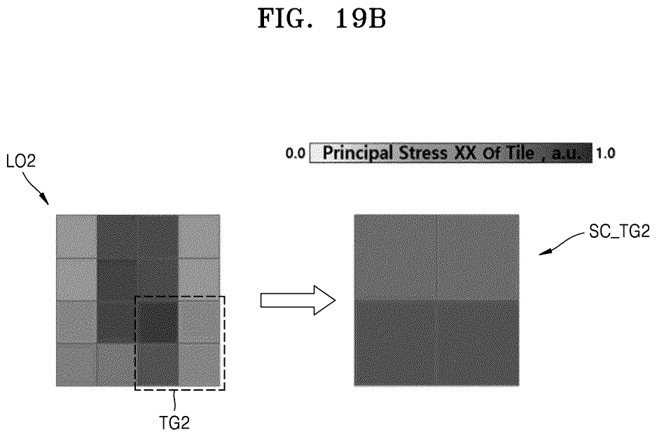

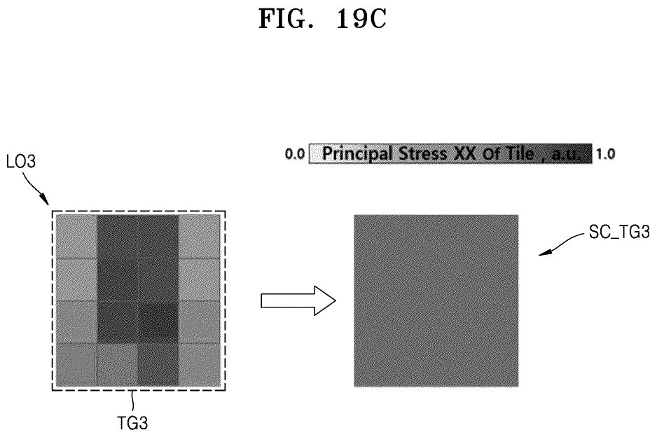

In operation S331a, the layout simulation system 100 may generate a local stress value by performing a stress averaging task based on a stress simulation result value according to operation S324. A detailed description about the stress averaging task is described below with reference to FIGS. 19A-C.

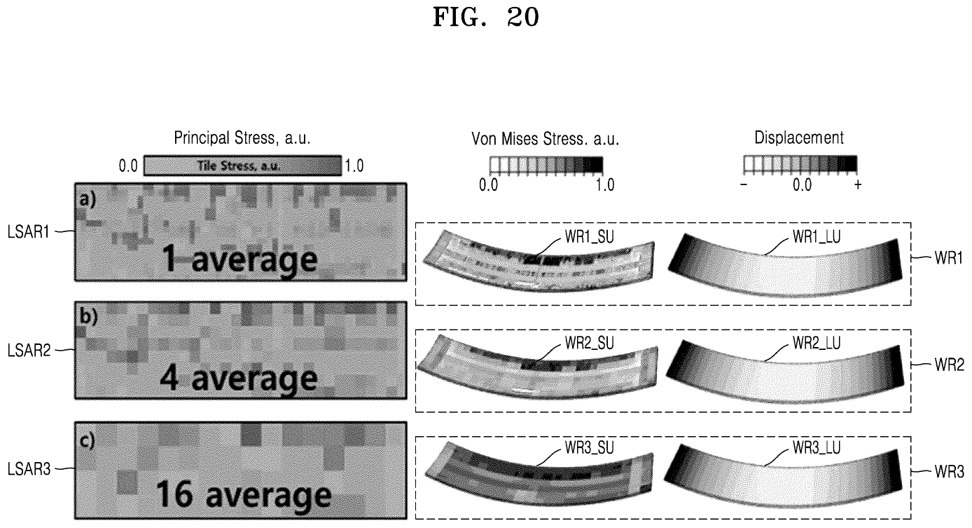

In operation S332a, the layout simulation system 100 may generate a warpage simulation result value by performing a warpage simulation based on the local stress value generated in operation S331a. A detailed description about the warpage simulation is described below with reference to FIGS. 20 to 22.

In embodiments, a user may change a design rule based on the warpage simulation result value according to operation S332a. The layout simulation system 100 may terminate the layout analysis or perform the layout analysis again based on the changed design rule by going back to operation S310, depending on whether the design rule has changed. For example, when the warpage simulation result value is greater that a preset warpage reference value, the user may select to perform the layout analysis again by chaining the design rule. For example, when the warpage simulation result value is less than the preset warpage reference value, the user may determine to terminate the layout analysis without changing the design rule.

FIG. 18 is a flowchart showing an embedded warpage simulation method according to embodiments. In detail, FIG. 18 is a flowchart showing operation S330 of FIG. 3. FIG. 18 may be described with reference to FIGS. 1 to 4 and 17, and redundant descriptions thereof may be omitted.

Referring to FIG. 18, operation S330b may correspond to operation S330 of FIG. 3. In the specification, an embedded warpage simulation may refer to performing a warpage simulation considering a local pattern (e.g., a weak pattern detected through operation S340).

In operation S331b, the layout simulation system 100 may generate a local stress value like operation S331a of FIG. 17.

In operation S332b, the layout simulation system 100 may generate a warpage simulation result value by performing the embedded warpage simulation based on the local stress value and weak pattern generated in operation S331b. In this state, a weak pattern may refer to the pattern detected through operation S340.

In embodiments, the user may change the design rule based on the warpage simulation result value according to operation S332b. The layout simulation system 100 may terminate the layout analysis or perform the layout analysis again based on the changed design rule by going back to operation S310, depending on whether the design rule has changed

FIGS. 19A, 19B, and 19C are diagrams illustrating a local stress averaging task according to embodiments. FIGS. 19A, 19B, and 19C may be described with reference to FIGS. 2 to 5 and 16 to 18, and redundant descriptions thereof may be omitted.

Referring to FIGS. 19A, 19B, and 19C, the local stress value may be a value calculated by averaging stress values of each of data points on the tiled layout data into a tile group unit. In other words, the local stress value may mean an average value of stress values of data points existing on tiles included in a tile group. The local stress value may be one value provided for each tile group, and a value representing the corresponding tile group. The local stress value may be visually represented using a shade gradation illustrated in FIGS. 19A-C according to a relative size. The tile group unit may refer to a grouping of at least one tile. In other words, a plurality of tiles may be grouped into a plurality of tile groups. Each of tile groups may include at least one tile. For example, when the tile group unit includes one tile, the local stress value corresponding to the tile illustrated in FIG. 16 may be an average value of stress values of the first data point DP1 to the eighth data point DP8. As used herein, a tile group may also be referred to as a tile group unit, and vice versa.

In embodiments, a user for grouping tiles may be determined according to a preset tile group unit, and may be changed according to user's manipulation of the layout simulation system 100.

In embodiments, there may be a first layout LO1, a second layout LO2, and a third layout LO3 including sixteen tiles, as illustrated in FIGS. 19A-C. The three layouts illustrated in FIGS. 19A-C may all be the same layouts. However, the tile group units in the layouts may be different from each other. Each layout including sixteen tiles as in FIGS. 19A-C is an example for explanation, and the inventive concept is not limited thereto. In embodiments, the tile group may be configured such that the tile group includes only one tile like a first tile group TG1 of FIG. 19A. That is, in the case of FIG. 19A, the tile group unit may be 1. In this case, the number of tile groups corresponding to the first layout LO1 may be 16. A first stress contour SC_TG1 may be a stress contour corresponding to the first layout LO1. The first stress contour SC_TG1 may be represented based on local stress values of each tile group (i.e., sixteen local stress values). In embodiments, the tile group may be configured such that the tile group includes four tiles like a second tile group TG2 of FIG. 19B. That is, in the case of FIG. 19B, the tile group unit may be 4. In this case, the number of tile groups corresponding to the second layout LO2 may be 4. A second stress contour SC_TG2 may be a stress contour corresponding to the second layout LO2. The second stress contour SC_TG2 may be represented based on local stress values of each tile group (i.e., four local stress values). In embodiments, the tile group may be configured such that the tile group includes sixteen tiles like a third tile group TG3 of FIG. 19C. That is, in the case of FIG. 19C, the tile group unit may be 16. In this case, the number of tile groups corresponding to the third layout LO3 may be 1. A third stress contour SC_TG3 may be a stress contour corresponding to the third layout LO3. The third stress contour SC_TG3 may be represented based on the local stress value of the tile group (i.e., one local stress value). As such, by performing the local stress averaging task through the layout simulation system 100, the user may easily identify areas where stress is excessively concentrated within a particular tile and accordingly identify areas that need improvement in circuit design.

FIG. 20 is a diagram illustrating a warpage simulation according to embodiments. FIG. 20 may be described with reference to FIGS. 2 to 5 and 17, 18, 19A, 19B, and 19C, and redundant descriptions thereof may be omitted.

Referring to FIG. 20, images in FIG. 20 are visual representation of results of the warpage simulation according to operation S332a or operation S332b.

In embodiments, when a tile group includes one tile (1 average in FIG. 20), a result of the local stress averaging task may be visually represented as a first local stress averaging result LSAR1. The layout simulation system 100 may perform a warpage simulation based on the first local stress averaging result LSAR1. The layout simulation system 100 may generate a first warpage simulation result WR1 as a visual result of the warpage simulation. In this state, the first warpage simulation result WR1 may correspond to the overall layout (i.e., the overall chip). The first warpage simulation result WR1 may include a first stress unit result WR1_SU and a first length unit result WR1_LU. The layout simulation system 100 may generate a warpage value based on the first length unit result WR1_LU. The first stress unit result WR1_SU may be represented as a stress contour. Furthermore, a degree to which a chip is bent may be defined by a length unit (e.g., μm), and the first length unit result WR1_LU is a visual representation thereof. For example, it is assumed that a portion where a chip is not bent is a reference point and that a degree of bending at the reference point is 0 μm, which may be displayed in a medium shade on a contour. A portion of the chip which is bent most in a first direction (a vertically upward direction) based on the reference point may be displayed in a darker shade. A portion of the chip which is most bent in a second direction (a vertically downward direction) opposite to the first direction based on the reference point may be displayed in a lighter shade. In this case, the difference between the value corresponding to the most bent portion in the first direction (i.e., the darker shade section, for example, +25 μm) and the value corresponding to the most bent portion in the second direction (i.e., the lighter shade section, for example, −25 μm) may be the warp value (e.g., 50 μm).

In embodiments, when the tile group includes four tiles (4 average in FIG. 20), a result of the local stress averaging task may be visually represented as a second local stress averaging result LSAR2. The layout simulation system 100 may perform a warpage simulation based on the second local stress averaging result LSAR2. The layout simulation system 100 may generate a second warpage simulation result WR2 as a visual result of the warpage simulation. The second warpage simulation result WR2 may include a second stress unit result WR2_SU and a second length unit result WR2_LU. As the second local stress averaging result LSAR2 is obtained from grouping more tiles into one group compared to the first local stress averaging result LSAR1, the second stress unit result WR2_SU may be visually expressed in a simpler manner than the first stress unit result WR1_SU. In this case, the second length unit result WR2_LU may also be similar to the first length unit result WR1_LU.

In embodiments, when the tile group includes sixteen tiles (16 average in FIG. 20), a result of the local stress averaging task may be visually represented as a third local stress averaging result LSAR3. The layout simulation system 100 may perform a warpage simulation based on the third local stress averaging result LSAR3. The layout simulation system 100 may generate a third warpage simulation result WR3 as a visual result of the warpage simulation. The third warpage simulation result WR3 may include a third stress unit result WR3_SU and a third length unit result WR3_LU. As the third local stress averaging result LSAR3 is obtained from grouping more tiles into one group compared to the second local stress averaging result LSAR2, the third stress unit result WR3_SU may be visually expressed in a simpler manner than the second stress unit result WR2_SU. In this case, the third length unit result WR3_LU may also be similar to the second length unit result WR2_LU.

In embodiments, the layout simulation system 100 may perform a warpage simulation considering a temperature parameter included in the process condition data PD. For example, as temperature applied to a chip increases, warpage of the chip may increase further, a warpage simulation may be performed considering that temperature changes as a semiconductor chip undergoes various manufacturing processes.

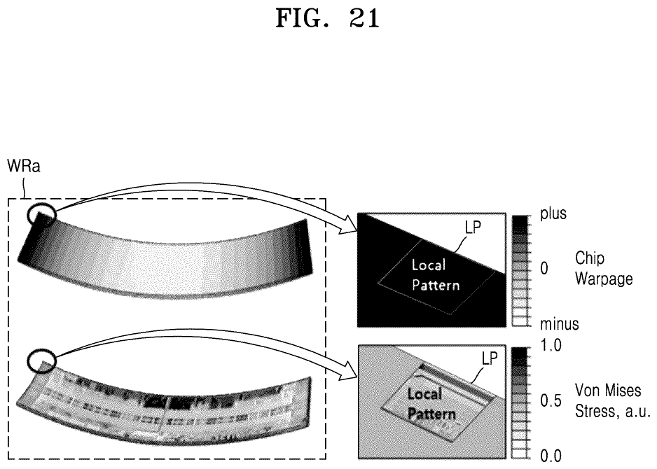

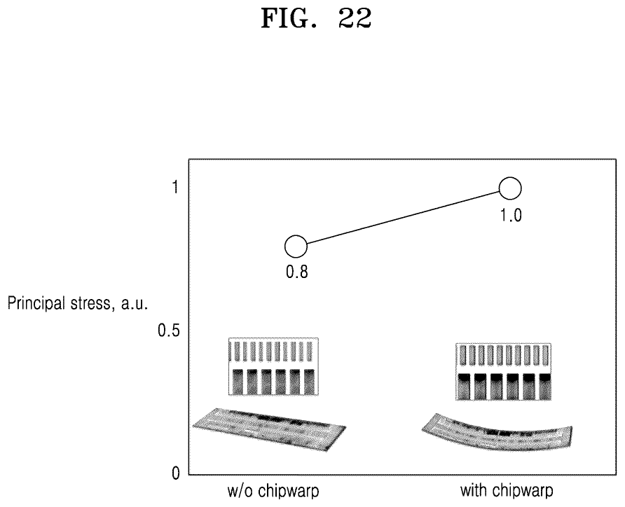

FIGS. 21 and 22 are diagrams illustrating an embedded warpage simulation according to embodiments. FIGS. 21 and 22 may be described with reference to FIGS. 2 to 5 and 17 to 20, and redundant descriptions thereof may be omitted.

Referring to FIG. 21, when the layout simulation system 100 performs an embedded warpage simulation according to operation S332b, it may be seen that a stress value of a local pattern LP is embedded in a warpage simulation result WRa. In some embodiments, the local pattern LP may refer to the weak pattern detected through operation S340.

Referring to FIG. 22, a graph shows a correlation between the stress applied to the local pattern LP depending on the occurrence of warpage on a chip (which may refer to a chip that is visually represented as a warpage simulation result).

In embodiments, the layout simulation system 100 may simulate, through an embedded warpage simulation, a stress value applied to the local pattern LP when warpage does not occur on a chip and a stress value applied to the local pattern LP when warpage occurs on a chip. For example, when a stress value applied to the local pattern LP (a value obtained by averaging the stress values of data points of a local pattern) when warpage occurs on a chip is defined as 1, it may be seen that a stress value applied to the local pattern LP (the value obtained by averaging the stress values of data points of a local pattern) when warpage does not occur on a chip is reduced to 0.8.

Accordingly, the layout simulation system 100 may precisely analyze the influence of warpage of a chip on the local pattern LP by additionally reflecting the local pattern LP aside from the local stress averaging result. The user may correct the design or improve the process based on the result. For example, by attaching a film on a backside of a substrate, a chip may be designed to prevent warpage of the chip, and thus stress applied to the local pattern LP may be reduced.

FIG. 23 is a flowchart showing a weak pattern detection method according to embodiments. In detail, FIG. 23 is a flowchart showing operation S340 of FIG. 3. Furthermore, FIG. 23 is a flowchart showing a weak pattern detection method when the experiment data ED does not exist. FIG. 23 may be described with reference to FIGS. 2 to 4 and 16, and redundant descriptions thereof may be omitted.

Referring to FIG. 23, operation S340a may correspond to operation S340 of FIG. 3.

In operation S341a, the layout simulation system 100 may sort the stress simulation result values for each tile according to operation S324 in order of stress value size.

In embodiments, sorting the stress simulation result values may be performed in ascending or descending order.

In operation S342a, the layout simulation system 100 may compare the stress simulation result values with the reference stress value, and detect a data point having a stress value greater than the reference stress value. The layout simulation system 100 may detect a pattern including the detected data point as a weak pattern.

In embodiments, the reference stress value may be a value previously input to the layout simulation system 100. Alternatively, the reference stress value may be a value input by a user of the layout simulation system 100.

In embodiments, the reference stress value is assumed to be 320 mpa. Referring to FIG. 16, the stress values of the seventh data point DP7 and the eighth data point DP8 are each 330 mpa, which may be greater than the reference stress value. In this state, the layout simulation system 100 may detect the pattern having the seventh data point DP7 and the eighth data point DP8 as a weak pattern.

FIG. 24 is a flowchart showing a weak pattern detection method according to embodiments. In detail, FIG. 24 is a flowchart showing operation S340 of FIG. 3. Furthermore, FIG. 24 is a flowchart showing a weak pattern detection method when the experiment data ED exists. FIG. 24 may be described with reference to FIGS. 2 to 4, 16, and 23, and redundant descriptions thereof may be omitted.

Referring to FIG. 24, operation S340b may correspond to operation S340 of FIG. 3.

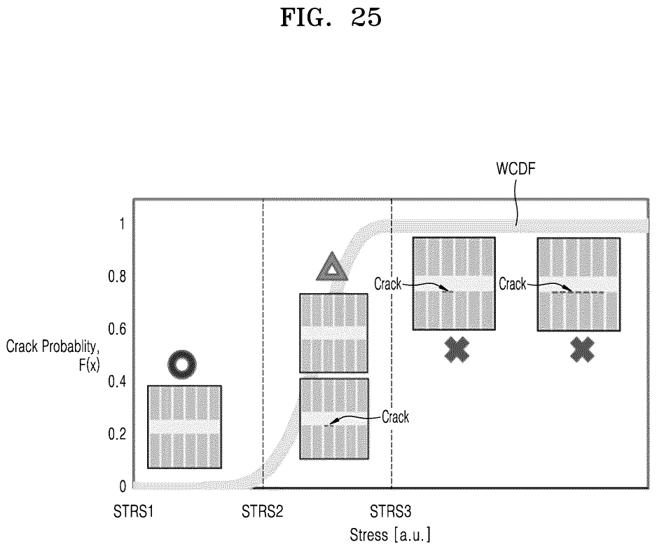

Referring to FIG. 24, in operation S341b, the layout simulation system 100 may calculate crack probability by comparing stress values of the stress simulation result values for each tile according to operation S324 with the experiment data ED. Calculating the crack probability is described below with reference to FIG. 25.

In operation S342b, the layout simulation system 100 may calculate crack probability by substituting a stress value of each of data points on tiled layout data into the Weibull cumulative distribution function (WCDF) defined with scale parameters and shape parameters, crack probability corresponding to the stress value may be calculated. The layout simulation system 100 may detect a data point where crack probability is greater than the reference crack probability among data points on the tiled layout data. The layout simulation system 100 may detect a pattern including the detected data point as a weak pattern.

In embodiments, the reference crack probability may be a value previously input to the layout simulation system 100. Alternatively, the reference crack probability may be a value input by the user of the layout simulation system 100.

In operation S343b, the layout simulation system 100 may calculate consistency between the calculation result of operation S342b and the experiment data ED. The consistency may refer to a degree of matching between the crack probability calculated according to operation S342b and the actual experiment data ED (e.g., crack probability calculated by measuring cracks according to the stress value on an actual semiconductor chip). High consistency may mean that a simulation model reflects an actual process well, whereas low consistency may mean that a model modification or process change is required.

In embodiments, when the consistency calculated through operation S343b is not satisfactory, the user may determine whether to readjust process conditions or the model for higher consistency.

FIG. 25 is a graph showing a method of calculating a crack probability, according to embodiments.

Referring to FIG. 25, the crack probability may be calculated through WCDF. WCDF may be defined as the following Equation 1.

$$F ( x ) = 1 - {exp [ - \frac{x}{λ} ]}^{k} for x \geq 0 \qquad [ Equation 1 ]$$

In Equation 1, a variable x may denote a stress value of a particular data point. F(x) may denote a cumulative probability that an event (e.g.: breakage, crack, etc.) will occur for values less than or equal to the variable x. 2 may be referred to as a scale parameter, and k may be referred to as a shape parameter.

The layout simulation system 100 may substitute the stress value of a data point into Equation 1 as the variable x, and determine whether the pattern including the data point is a weak pattern, based on a result of Equation 1.

In embodiments, when the value of the variable x is greater than a first value STRS1 and less than a second value STRS2, a crack generation probability at the data point corresponding to the variable x may be 0 or close to 0. When the value of the variable x is greater than the second value STRS2 and less than a third value STRS3, the crack generation probability at the data point corresponding to the variable x may be between 0 and 1. When the value of the variable x is greater than the third value STRS3, the crack generation probability at the data point corresponding to the variable x may be 1 or close to 1. In this state, it is assumed that the reference crack probability is 0.5. The assumption that the reference crack probability is 0.5 is an example for explanation, and the inventive concept is not limited thereto. When a stress value of a certain data point is substituted into Equation 1 as the variable x, a result value of Equation 1 is calculated such that a probability greater than 0.5, the layout simulation system 100 may determine a pattern including the data point as a weak pattern.

In embodiments, the scale parameters and the shape parameters may be values included in the experiment data ED. The scale parameters and the shape parameters included in the experiment data ED may be values derived from observing actual semiconductor chips in advance.

In embodiments, the scale parameters and the shape parameters may have different values depending on the material used for manufacturing semiconductor chips. For example, during the manufacturing of semiconductor chips, the scale parameters and the shape parameters may have different values depending on an adhesive material formed on a metal layer and an insulating interlayer, and as the material has stronger adhesion, the scale parameters and the shape parameters may have greater values. The layout simulation system 100 may perform a simulation considering the type of the adhesive material described above.

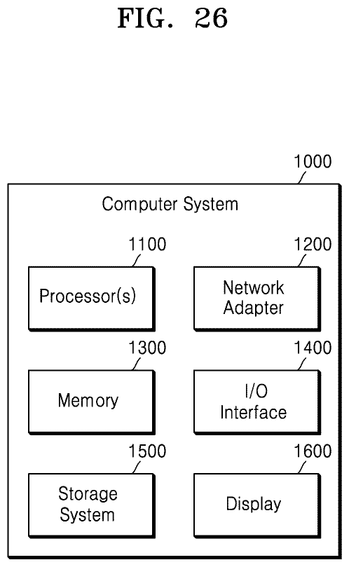

FIG. 26 is a block diagram showing a computer system 1000 according to embodiments.

The computer system 1000 of FIG. 26 may correspond to the layout simulation system described above with reference to the drawings.

The computer system 1000 may refer to a certain system including a general or special purpose computing system. For example, the computer system 1000 may include a personal computer, a server computer, a laptop computer, a home appliance product, or the like. As illustrated in FIG. 26, the computer system 1000 may include at least one processor 1100, a network adapter 1200, a memory 1300, an input/output (I/O) interface 1400, a storage system 1500, and a display 1600.

The at least one processor 1100 may execute a program module including computer system executable instructions. The program module may include routines, programs, objects, components, logics, data structures, or the like for performing a particular task or implementing a particular abstract data type. The memory 1300 may include a computer system readable medium of a volatile memory type such as random access memory (RAM). The at least one processor 1100 may access the memory 1300 and execute instructions loaded on the memory 1300. The storage system 1500 may store information in a non-volatile manner, and in some embodiments, may include at least one program product comprising a program module configured to perform training of machine learning models for the layout simulation described above with reference to the drawings. A program may include, as a non-limiting example, an operating system, at least one application, other program modules, and program data.

The network adapter 1200 may provide an access to a local area network (LAN), a wide area network (WAN), and/or a public network (e.g., the Internet). The I/O interface 1400 may provide a communication channel with a peripheral device, such as a keyboard, a pointing device, an audio system, etc. The display 1600 may output various pieces of information for a user to check.

In some embodiments, the method of simulating a layout of an integrated circuit described above with reference to the drawings may be implemented by a computer program product. The computer program may include a non-transitory computer-readable medium (or storage medium) containing computer-readable program instructions for causing the at least one processor 1100 to perform image processing and/or training of models. The computer-readable instructions may include, as a non-limiting example, assembler instructions, instruction set architecture (ISA) instructions, machine instructions, machine-dependent instructions, micro code, firmware instructions, state setting data, or source code or object code written in at least one programming language.

The computer-readable medium may be any type of medium capable of non-transitory holding and storing instructions that are executed by the at least one processor 1100 or any instruction executable device. The computer-readable medium may include an electronic storage device, a magnetic storage device, an optical storage device, an electromagnetic storage device, a semiconductor storage device, or any combination thereof, but the inventive concept is not limited thereto. For example, the computer-readable medium may include a portable computer diskette, hard disk, random access memory (RAM), read-only memory (ROM), electrically erasable read only memory (EEPROM), flash memory, static random access memory (SRAM), CD, DVD, memory stick, floppy disk, a mechanically encoded device such as a punch card, or any combination of these.

Embodiments are disclosed in the drawings and the specification as above. While the inventive concept has been particularly shown and described with reference to example embodiments using specific terminologies, the embodiments and terminologies should be considered in descriptive sense only and not for purposes of limitation. Therefore, it will be understood by those of ordinary skill in the art that various changes in form and details may be made therein without departing from the scope of the inventive concept as defined by the following claims.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

While the inventive concept has been particularly shown and described with reference to example embodiments thereof, it will be understood that various changes in form and details may be made therein without departing from the scope of the following claims.

What is claimed is:

1. A method of simulating a layout of an integrated circuit manufactured by a semiconductor process, the method comprising:
generating tiled layout data including a plurality of tiles by tiling layout data defining the layout of the integrated circuit, wherein the layout data comprises at least one layer;
generating a simulation structure and a mesh structure based on the tiled layout data;
generating a stress simulation result value by performing a stress simulation on each of the plurality of tiles;
generating a local stress value by performing a stress averaging task based on the stress simulation result value; and
generating a warpage simulation result value by performing a warpage simulation based on the local stress value.

2. The method of claim 1, wherein the generating of the stress simulation result value comprises:
extracting physical properties information and intrinsic stress information based on process condition data including at least one process condition through a process condition model corresponding to the semiconductor process; and
generating the stress simulation result value by performing a simulation on each of the plurality of tiles based on the physical properties information and the intrinsic stress information.

3. The method of claim 1, wherein the simulation structure comprises:
a bulk structure that represents a layout of a substrate of the integrated circuit in three-dimensions;
a shell structure that represents the at least one layer in a plan view; and
a tie condition that represents connection information between the bulk structure and the shell structure.

4. The method of claim 1, wherein the at least one layer comprises a plurality of layers,
wherein the mesh structure is generated at a first density in a select layer selected from among the plurality of layers,
wherein the mesh structure is generated at a second density in layers other than the select layer among the plurality of layers, and
wherein the first density is greater than the second density.

5. The method of claim 1, wherein the plurality of tiles comprise a first tile and a second tile adjacent to the first tile, and
wherein the second tile overlaps at least part of the first tile.

6. The method of claim 1, wherein the generating of the tiled layout data comprises changing curvatures of patterns included in the tiled layout data based on a preset curvature value.

7. The method of claim 1, wherein the stress simulation result value comprises a coordinate value and a stress value of each of data points on the tiled layout data.

8. The method of claim 7, wherein the generating of the local stress value comprises generating a local stress value for a tile group unit by averaging the stress value of each of the data points on the tiled layout data in the tile group unit, and
wherein the tile group unit comprises a grouping of at least one of the plurality of tiles.

9. The method of claim 1, wherein the warpage simulation result value comprises a warpage value corresponding to the layout data.

10. A method of simulating a layout of an integrated circuit manufactured by a semiconductor process, the method comprising:
generating tiled layout data including a plurality of tiles by tiling layout data defining the layout of the integrated circuit, wherein the layout data comprises at least one layer;
generating a simulation structure and a mesh structure based on the tiled layout data;
generating a stress simulation result value by performing a stress simulation on each of the plurality of tiles; and
detecting a weak pattern from among a plurality of patterns included in the plurality of tiles based on the stress simulation result value.

11. The method of claim 10, wherein the stress simulation result value comprises a coordinate value and a stress value of each of data points on the tiled layout data.

12. The method of claim 11, wherein the detecting of the weak pattern comprises:
detecting a data point having a stress value greater than a reference stress value, from among the data points on the tiled layout data; and
detecting a pattern including the data point as the weak pattern, from among the plurality of patterns.

13. The method of claim 11, wherein the detecting of the weak pattern comprises:
calculating a crack probability corresponding to the stress value by substituting a stress value of each of the data points on the tiled layout data into a Weibull cumulative distribution function that is defined by a scale parameter and a shape parameter;
detecting a data point where the crack probability is greater than a reference crack probability, from among the data points on the tiled layout data; and
detecting a pattern including the data point as the weak pattern, from among the plurality of patterns.

14. The method of claim 13, wherein the scale parameter and the shape parameter are values included in pre-input experiment data.

15. The method of claim 13, wherein the scale parameter and the shape parameter have different values depending on a type of an adhesive material formed between a metal layer and an insulating interlayer defined in the layout data.

16. The method of claim 13, further comprising calculating a consistency value by comparing the crack probability with pre-input experiment data.

17. A method of simulating a layout of an integrated circuit manufactured by a semiconductor process, the method comprising:
generating tiled layout data including a plurality of tiles by tiling layout data defining the layout of the integrated circuit, wherein the layout data comprises at least one layer;
generating a simulation structure and a mesh structure based on the tiled layout data;
generating a stress simulation result value by performing a stress simulation on each of the plurality of tiles;
generating a local stress value by performing a stress averaging task based on the stress simulation result value;
detecting a weak pattern from among a plurality of patterns included in the plurality of tiles based on the stress simulation result value; and
generating a warpage simulation result value by performing a warpage simulation based on the local stress value and the weak pattern.

18. The method of claim 17, wherein the stress simulation result value comprises a coordinate value and a stress value of each of data points on the tiled layout data.

19. The method of claim 18, wherein the generating of the local stress value by performing the stress averaging task based on the stress simulation result value comprises generating a local stress value for a tile group unit by averaging the stress value in the tile group unit, and
wherein the tile group unit comprises a grouping of at least one of the plurality of tiles.

20. The method of claim 17, wherein the warpage simulation result value comprises a warpage value corresponding to the layout data and a stress value for each data point of the weak pattern.
